(19) United States
(12) Patent Application Publication
(10) Pub. No.: US 2011/0241095 A1
(43) Pub. Date: Oct. 6, 2011

(54) NONVOLATILE SEMICONDUCTOR MEMORY DEVICE AND METHOD OF FABRICATING THE SAME

(75) Inventors: Kikuko SUGIMAE, Kanagawa-ken (JP); Takayuki TOBA, Kanagawa-ken (JP)

(73) Assignee: Kabushiki Kaisha Toshiba, Tokyo (JP)

(21) Appl. No.: 13/051,784

(22) Filed: Mar. 18, 2011

(30) Foreign Application Priority Data
Mar. 30, 2010 (JP) P2010-079828

(51) Int. Cl. H01L 29/788; H01L 21/76

(52) U.S. Cl. 257/316; 438/404; 257/E29.3; 257/E21.54

(57) ABSTRACT

In one embodiment, a semiconductor memory device, including a memory cell having a floating gate electrode above a semiconductor substrate via a first gate insulator and a control gate electrode above the floating gate electrode via a first inter-gate insulator, a contact electrode having a bottom electrode contacted to an upper surface of the semiconductor substrate, top electrodes via a second inter-gate insulators on both edge portions of the bottom electrode and a plug electrode between the top electrodes, the plug electrode contacted to an upper surface of the bottom electrode.

### CROSS REFERENCE TO RELATED APPLICATION

This application is based upon and claims the benefit of priority from prior Japanese Patent Application No. 2010-079828, filed on Mar. 30, 2010, the entire contents of which are incorporated herein by reference.

### FIELD

Exemplary embodiments described herein generally relate to a nonvolatile semiconductor memory device and a method of fabricating the semiconductor memory device and more particularly, to a contact structure in the nonvolatile semiconductor memory device.

### BACKGROUND

A nonvolatile semiconductor memory device, for example, a NAND flash memory has been installed in various kinds of electron devices.

As memory capacitors in the NAND flash memory device has been increased, shrinking of memory cells has been preceded.

Here, both contact resistance have been high and aspect ratio in a contact structure of the NAND flash memory have significantly become tight for manufacturing. Therefore, improvement approaches on the contact structure are proposed in conventional technology.

### BRIEF DESCRIPTION OF THE DRAWINGS

FIG. 1 is a plane view showing a structure of a memory cell array in a semiconductor memory device according to a first embodiment.

FIGS. 2A-2D are cross sectional views showing a semiconductor memory cell taken along A-A line, B-B line, C-C line and D-D line in FIG. 1, respectively, according to the first embodiment.

FIGS. 3A-3D are cross sectional views showing fabricating processes of the semiconductor memory device taken along A-A line, B-B line, C-C line and D-D line in FIG. 1, respectively, according to the first embodiment.

FIGS. 4A-4D are cross sectional views, subsequently FIGS. 3A-3D, respectively, showing the fabricating processes of the semiconductor memory device according to the first embodiment.

FIG. 5 is a plane view, subsequently FIGS. 4A-4D, showing the fabricating processes of the semiconductor memory device according to the first embodiment.

FIG. 6 is a plane view, subsequently FIG. 5, showing the fabricating processes of the semiconductor memory device according to the first embodiment.

FIG. 7 is a plane view, subsequently FIG. 6, showing the fabricating processes of the semiconductor memory device according to the first embodiment.

FIGS. 8A-8D are cross sectional views, subsequently FIG. 7, showing the fabricating processes of the semiconductor memory device according to the first embodiment.

FIG. 9 is a plane view, subsequently FIG. 8, showing the fabricating processes of the semiconductor memory device according to the first embodiment.

FIGS. 10A-10D are cross sectional views, subsequently FIG. 9, showing the fabricating processes of the semiconductor memory device according to the first embodiment.

FIGS. 11A-11D are cross sectional views, subsequently FIGS. 10A-10D, respectively, showing the fabricating processes of the semiconductor memory device according to the first embodiment.

FIGS. 12A-12D are cross sectional views, subsequently FIGS. 11A-11D, respectively, showing the fabricating processes of the semiconductor memory device according to the first embodiment.

FIGS. 13A-13D are cross sectional views, subsequently FIGS. 12A-12D, respectively, showing the fabricating processes of the semiconductor memory device according to the first embodiment.

FIGS. 14A-14D are cross sectional views of a semiconductor memory device showing fabricating processes of the semiconductor memory device taken along A-A line, B-B line, C-C line and D-D line in FIG. 1, respectively, according to a modification of the first embodiment.

FIGS. 15A-15D are cross sectional views, subsequently FIGS. 14A-14D, respectively, showing the fabricating processes of the semiconductor memory device according to the modification of the first embodiment.

FIG. 16 is a cross sectional view showing a semiconductor memory cell taken along A-A line according to the first embodiment.

### DETAILED DESCRIPTION

In one embodiment, a semiconductor memory device, including a memory cell having a floating gate electrode above a semiconductor substrate via a first gate insulator and a control gate electrode above the floating gate electrode via a first inter-gate insulator, a contact electrode having a bottom electrode contacted to an upper surface of the semiconductor substrate, top electrodes via a second inter-gate insulators on both edge portions of the bottom electrode and a plug electrode between the top electrodes, the plug electrode contacted to an upper surface of the bottom electrode.

Embodiments will be described below in detail with reference to the attached drawings mentioned above.

Throughout the attached drawings, similar or same reference numerals show similar, equivalent or same components.

### First Embodiment

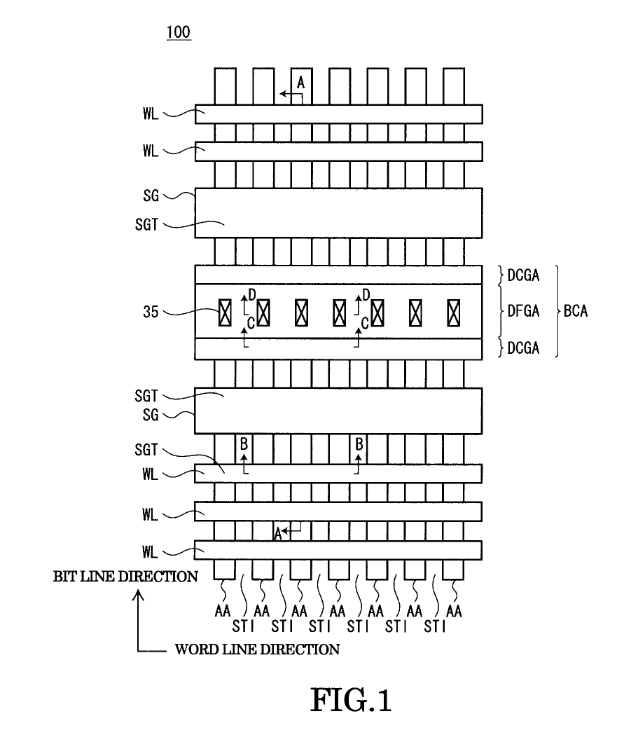

A plane structure of a memory cell array in a semiconductor memory device according to a first embodiment, for example, is described by using FIG. 1.

A NAND flash memory is explained as an example for the semiconductor memory device in this embodiment.

As shown in FIG. 1, a memory cell array 100 including a plurality of memory cells MC is extended along a bit line (BL) direction and includes a plurality of a plurality of active areas AA and a plurality of isolation insulators STI along a word line (WL) direction which is intersected with the BL direction. Each of the active areas AA is arranged with a designated interval. Each of the isolation insulators STI is arranged between the adjacent active areas AA. Further, the memory cell array 100 includes word lines WL extended along the word line direction, and each of the word lines WL is arranged with a designated interval towards the BL line direction. Each of the memory cells MC is provided at each intersection of the active area AA and the word line WL. The memory cells MC are arranged in series to the bit line direction to form a memory cell column.

A plurality of selection gates SG are provided at both edges of the memory cell column extended to the word line direction. A plurality of selection gate transistors SGT are respectively formed at intersections in each of the selection gate SG and the active area AA. A memory cell string includes memory cells MC connected in series and the selection gate transistors SGT provided at both edges of the memory cells MC. Further, the selection gates SG are adjoined in the bit line direction, a bit line contact area BCA is arranged between the selection gates SG. The bit line contact area BCA is separated into side-wall portions DCGA and a connection portion DFGA, the connection portion DFGA is sandwiched between the side-wall portions DCGA in the bit line direction.

A plurality of contact plugs 35 are provided in the connection portion DFGA.

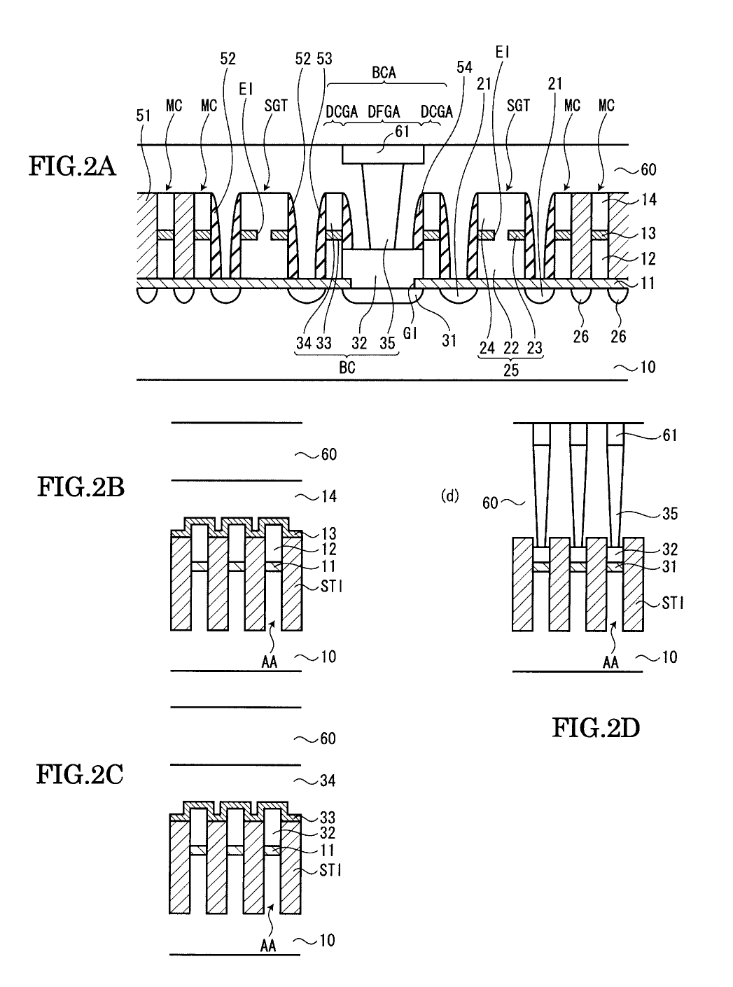

A cross-sectional structure of the memory cell array in the semiconductor memory device according to the first embodiment, for example, is described by using FIGS. 2A-2D. FIGS. 2A-2D are cross sectional views showing the memory cell array taken along A-A line, B-B line, C-C line and D-D line in FIG. 1, respectively, according to the first embodiment.

As shown in FIG. 2A, the memory cell MC includes a floating gate electrode 12 provided on a semiconductor substrate 10 via a gate insulator 11, a control gate electrode 14 provided on the floating gate electrode 12 via a first inter-gate insulator 13. Diffusion layers 26 as a source-drain diffusion layer is formed on a surface of the semiconductor substrate 10 between the adjacent memory cells MC. Here, a memory transistor MT is constituted with the memory cell MC, the gate insulator 11 and the diffusion layers 26.

The selection gate transistor SGT includes a gate electrode 25 provided on the semiconductor substrate 10 via the gate insulator 11 and diffusion layers 21 as a source-drain diffusion layer formed to sandwich the gate electrode 25. The gate electrode 25 includes a lower layer gate electrode 22 and an upper layer gate electrode 24. The lower layer gate electrode 22 is formed of the same material as the floating gate electrode 12. The upper layer gate electrode 24 is formed on the lower layer gate electrode 22 via a second inter-gate insulator 23 with an opening EI. The lower layer gate electrode 22 is electrically connected with the upper layer gate electrode 24 via the opening EI.

A bit line contact BC is provided in the bit line contact area BCA. The bit line contact BC includes a bottom electrode 32, a third inter-gate insulator 33, a top electrode 34 and a contact plug 35. The bottom electrode 32 is formed on an upper surface of the semiconductor substrate 10 and is connected to the upper surface of the semiconductor substrate 10 via the gate insulator 11 with the opening GI. The bottom electrode 32 is formed of the same material as the floating electrode 12. The third inter-gate insulator 33 is provided on an upper portion of the bottom electrode 32 at a side-wall portion DCGA of the bit line contact area BCA and is formed of the same material as the first inter-gate insulator 13. The top electrode 34 is provided on the bottom electrode 32 via the third inter-gate insulator 33 at the side-wall portion DCGA and is formed of the same material as the control gate electrode 14. The contact plug 35 is provided between the top electrodes 34 and is connected with an upper surface of the bottom electrode 32.

Here, the third inter-gate insulator 33 is provided at both edge portions of the bottom electrode 32 in the bit line direction. Further, the third inter-gate insulator 33 electrically separates between the bottom electrode 32 and the top electrode 34 in the side-wall portion DCGA. In other words, top electrode 34 is electrically separated to the bottom electrode 32 and the contact plug 35.

Further, the gate insulator 11 is provided between the bottom electrode 32 and the semiconductor substrate 10 at an edge portion of the bottom electrode 32 in the bit line contact BC. The gate insulator 11 provided at the edge portion can enlarge an alignment margin of the bottom electrode 32 at the opening GI mentioned after.

In addition, a diffusion layer 31 is formed on a surface of the semiconductor substrate 10 positioned immediately beneath the opening GI. The diffusion layer 31 may be connected to the diffusion layer 21. However, it is no problem that the two diffusion layers is set to be in a distance which electrical potential can be transferred from the bit line contact BC to the diffusion layer 21, when the diffusion layer 31 is separated to the diffusion layer 21. In a case of applying 2.5V to the bit line contact BC, for example, an inversion layer is formed immediately beneath the gate insulator 11 formed between the bottom electrode 32 and the semiconductor substrate 10, so that the diffusion layer 31 is connected to the diffusion layer 21. In the figures including mentioned after, a case which the diffusion layer 31 is separated to the diffusion layer 21, for example, is described for easily watching the structure.

An inter-layer insulator 51 is embedded in a portion between the memory cells MC. Further, first side-wall insulators 52 are provided on a side surface of the memory cell MC opposed to the gate electrode 25 and a side surface of the gate electrode 25. Further, a second side-wall insulator 53 is also provided on a side surface of the bit line contact BC opposed to the gate electrode 25. Moreover, a third side-wall insulators 54 is provided on a side surface of the top electrode 34 in the bit line contact BC and a bottom portion of the third side-wall insulators 54 is contacted to the bottom electrode 32. The contact plug 35 is arranged between the third side-wall insulators 54. Further, a width of the bottom electrode 32 is wider than a diameter of the contact plug 35 in the bit line direction.

An insulator 60 is formed to cover the memory cell MC, the gate electrode 25 and the bit line contact BC. An upper layer wiring 61 is disposed in the insulator 60 to connect to the bit line contact BC. Bit lines BL are disposed above the upper layer wiring 61.

As shown in FIG. 2B, the isolation insulators STI are disposed in the semiconductor substrate 10. The semiconductor substrate 10 sandwiched by each of the isolation insulators STI is each of the active areas AA.

The floating gate electrode 12 is disposed on the semiconductor substrate 10 via the gate insulator 11. A lower portion side surface of the floating gate electrode 12 is contacted to the isolation insulator STI. Further, an upper portion of the floating gate electrode 12 is protruded from an upper surface of the isolation insulator STI. The first inter-gate insulator 13 is continuously disposed on the upper surface of the isolation insulator STI and both upper surface and side surface of the floating gate electrode 12. The control gate electrode 14 is formed on the first inter-gate insulator 13. The insulator 60 is disposed above the control gate electrode 14.

As shown in FIG. 2C, the isolation insulators STI are disposed from the surface of the semiconductor substrate 10 into the inner portion of the semiconductor substrate 10 in a cross section of the bit line contact BC of the side-wall portion DCGA in the bit line contact area BCA. The semiconductor substrate 10 sandwiched between the isolation insulators STI is the active area AA.

The bottom electrode 32 is disposed on the semiconductor substrate 10 via the gate insulator 11.

A lower portion of the side surface of the bottom electrode 32 is contacted to the isolation insulator STI. Further, an upper portion of the bottom electrode 32 is protruded from the upper surface of the isolation insulator STI. The inter-gate insulator 33 is continuously disposed on the upper surface of the isolation insulator STI and both the upper surface and the side surface of the bottom electrode 32. The top electrode 34 is disposed on the inter-gate insulator 33. The insulator 60 is disposed above the top electrode 34.

Here, the top electrode 34 crosses over the active area AA and extends onto the adjacent bottom electrode 32. However, as shown in FIG. 2A, the contact plug 35 and the top electrode 34, respectively, are electrically separated each other by the side-wall insulator 54 and the insulator 60.

As shown in FIG. 2D, the isolation insulators STI are formed from the surface of the semiconductor substrate 10 to the inner portion of the semiconductor substrate 10 in a cross section of the bit line contact BC in the connection portion DFGA of the bit line contact area BCA. The semiconductor substrate 10 sandwiched between the isolation insulators STI is the active area AA. The diffusion layer 31 is formed in the surface of the semiconductor substrate 10.

The bottom electrode 32 is in contact with the surface of the semiconductor substrate 10. A side surface of the bottom electrode 32 is in contact with the isolation insulator STI. Further, an upper surface of the bottom electrode 32 is lower than the upper surface of the isolation insulator STI, the bottom electrode 32 disposed on each active area AA is separated by the isolation insulator STI. The contact plug 35 is in contact with the upper surface of each bottom electrode 32. The upper layer wiring 61 is in contact with the upper surface of the contact plug 35. Further, the contact plug 35 and the upper layer wiring 61 are covered with the insulator 60.

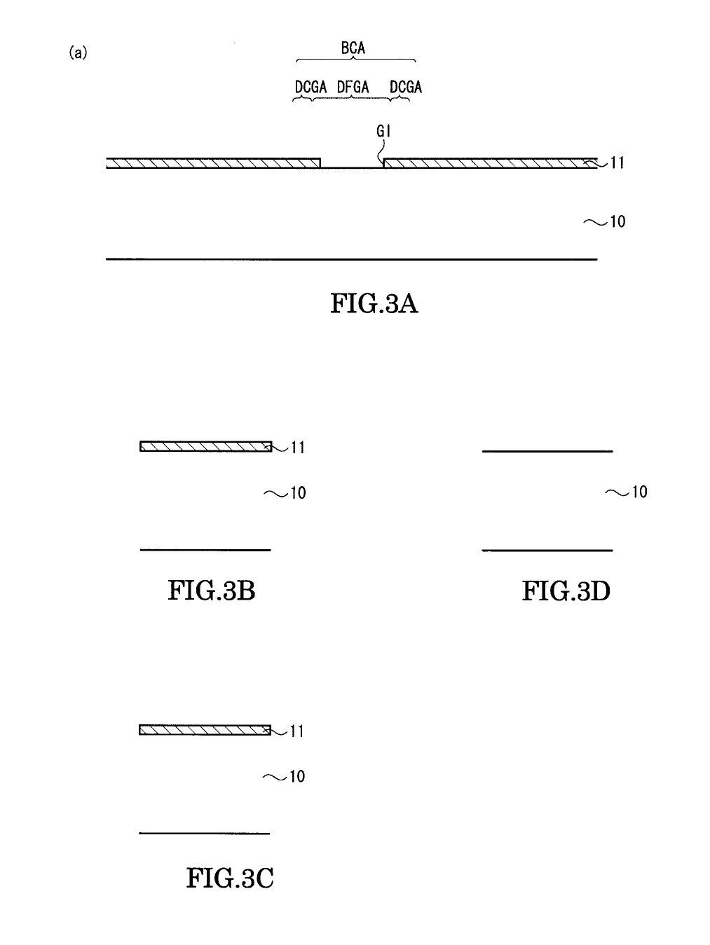

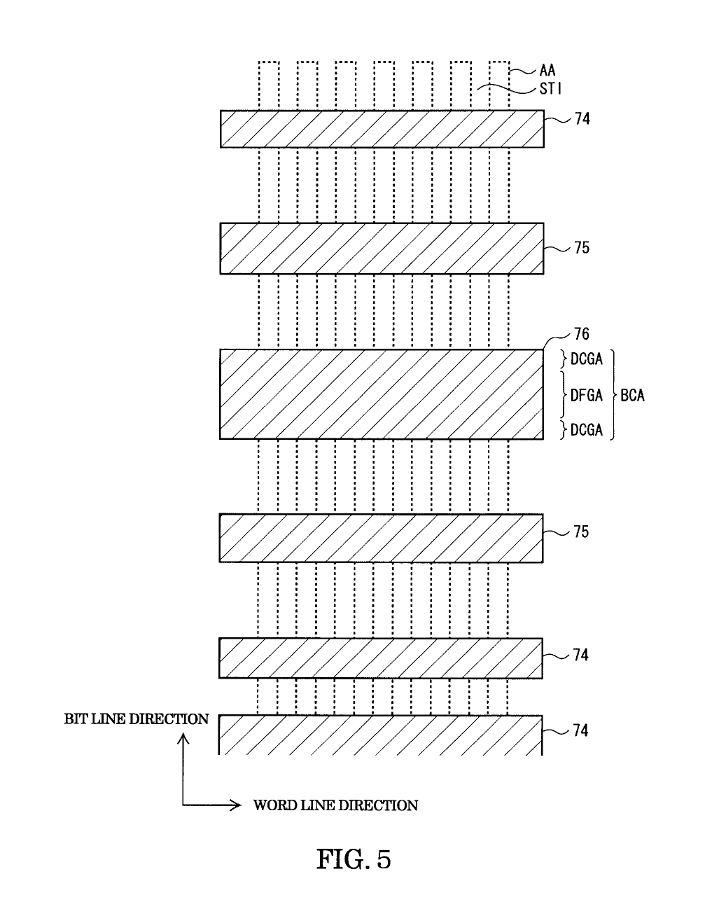

Next, a method of fabricating the semiconductor memory device in this embodiment is explained by using FIGS. 3-13. FIGS. 3A, 4A, 8A, 10A-13A are cross-sectional views taken along A-A line in FIG. 1. FIGS. 3B, 4B, 8B, 10B-15B are cross-sectional views taken along B-B line in FIG. 1. FIGS. 3C, 4C, 8C, 10C-13C are cross-sectional views taken along C-C line in FIG. 1. FIGS. 3D, 4D, 8D, 10D-13D are cross-sectional views taken along D-D line in FIG. 1. FIGS. 5-7, 9 are plane views corresponding to FIG. 1.

Not illustrated, n-type impurities are introduced into the semiconductor substrate 10, for example, using ion implantation or the like to form an n-well area. Successively, p-type impurities, boron or the like, are introduced into the n-well area in the semiconductor substrate 10, for example, using ion implantation or the like to form a p-well area.

As shown in FIG. 3A-3D, the gate insulator 11 composed of a silicon oxide film is formed on the surface of the semiconductor substrate 10, for example, by thermal oxidation. A portion of the gate insulator in the connection portion DFGA is selectively removed to form the opening GI. A width of the opening GI may not be equal to a width of the connection portion DFGA along the bit line direction.

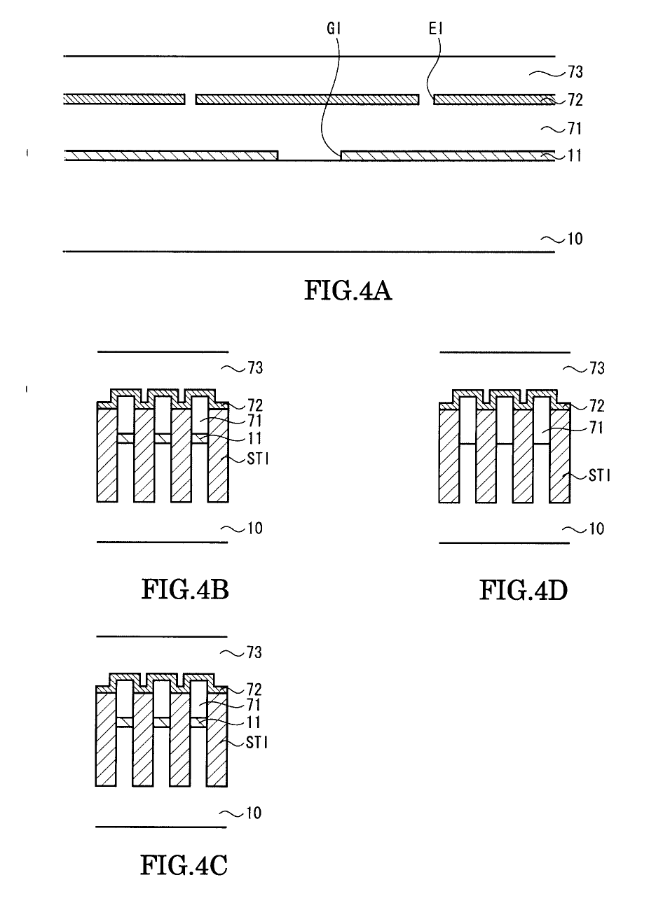

As shown in FIGS. 4A-4D, a first polycrystalline silicon 71, for example, is formed on the semiconductor substrate 10 and the gate insulator 11.

The semiconductor substrate 10, the gate insulator 11 and the first polycrystalline silicon 71 are selectively etching to form a trench, and an insulator is embedded into the trench to form the isolation insulator STI. An upper surface of the isolation insulator STI is fallen to be lower than an upper surface of the first polycrystalline silicon 71, and an inter-electrode insulator 72 formed of an ONO film, for example, is formed on the first polycrystalline silicon 71 and the isolation insulator STI.

The inter-electrode insulator 72 in the selection gate transistor SGT is partially removed to form the opening EI. Subsequently, a second polycrystalline silicon 73 is formed on the first polycrystalline silicon 71 and in an opening.

As shown in FIG. 5, a mask material, for example, composed of a silicon nitride film is formed on the second polycrystalline silicon 73 by lithography to form a pattern. As a result, a first mask pattern 74, a second mask pattern 75 and a third mask pattern 76 are formed, where the first mask pattern 74 with a designated interval in the bit line direction is extended along the word line direction, the second mask pattern 75 is formed in a selection gate SG and the third mask pattern 76 is formed in the bit line contact area BCA.

Meanwhile, a portion pointed by a dot line is not shown from a top view. However, the dot line is used for convenience in acknowledging the active area AA and the isolation insulator STI.

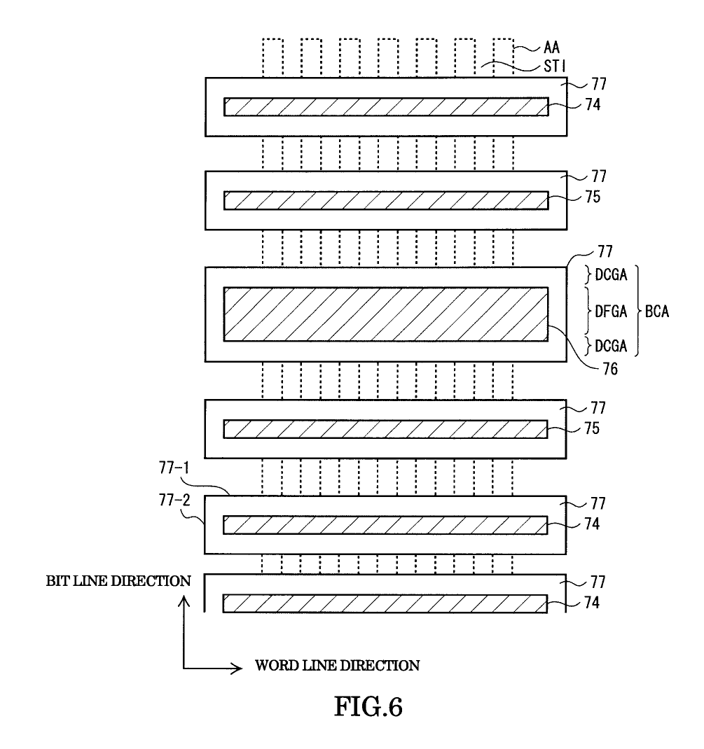

As shown in FIG. 6, the first mask 74, the second mask 75 and the third mask pattern 76 are slimmed, and a side-wall mask material formed of a silicon oxide film, for example, is entirely deposited. The side-wall mask material is processed by anisotropic etching to form side-wall mask patterns 77 surrounding the first mask 74, the second mask 75 and the third mask pattern 76. In other word, the side-wall mask patterns 77 are constituted with linear portions 77-1 extended along the word line direction and the linear connection portions 77-2 extended along the bit line direction, where both ends of each of the linear portion 77-1 is connected with an end of each of the linear portion 77-2, respectively, so that the side-wall mask patterns 77 is constituted as a ring shape. Further, linear connection portion 77-2 is formed on the isolation insulator STI and the second polycrystalline silicon 73 is formed under the linear connection portion 77-2, however the first polycrystalline silicon 71 is not formed under the linear connection portion 77-2. This is because the first polycrystalline silicon 71 is removed when the trench is formed to for forming the isolation insulator STI.

Here, a width of the side-wall mask pattern 77 in the bit line direction is equal to a width in the word line WL, and a width of the first mask pattern 74 in the bit line direction is equal to an interval of the word line WL in the bit line direction.

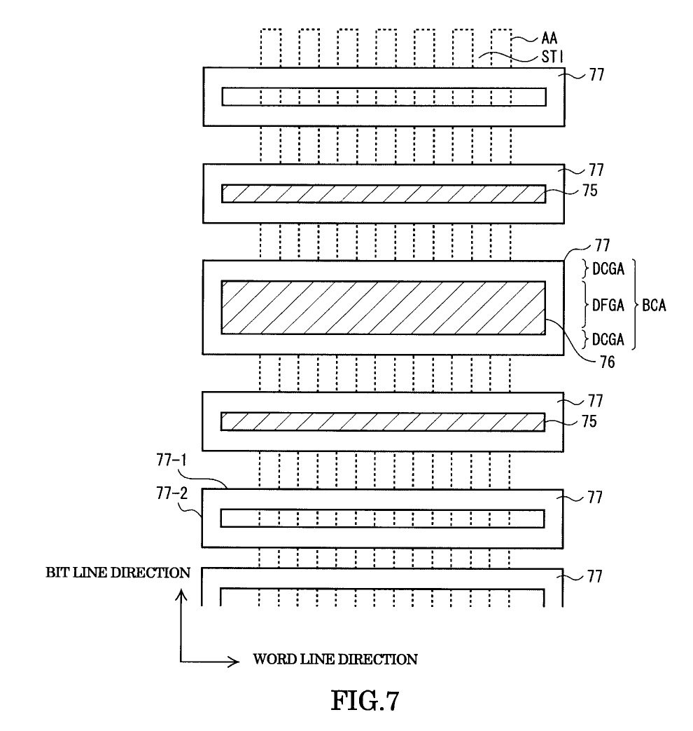

As shown in FIG. 7, the first mask pattern 74 is selectively removed by using lithography and etching. As a result, the plurality of the side-wall mask patterns 77 are formed. The side-wall mask pattern 77 with a closed loop extended to the word line direction is formed on a region where the memory cell MC is formed. At the same time, the third mask pattern 76 extended to the word line direction and the side-wall mask pattern 77 surrounding the third mask pattern 76 are formed in the bit line contact area BCA. In a similar fashion, the second mask pattern 75 extended to the word line direction and the side-wall mask pattern 77 surrounding the second mask pattern 75 are formed.

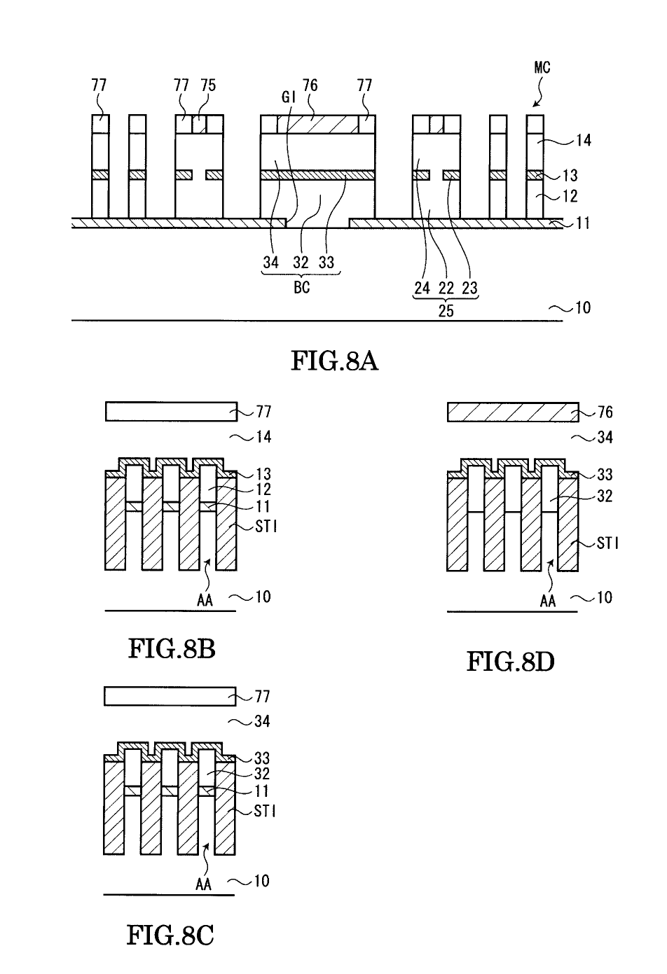

As shown in FIGS. 8A-8d, the first polycrystalline silicon 71, the inter-electrode insulator 72 and the second polycrystalline silicon 73 are removed by etching using the second mask pattern, the third mask pattern and side-wall mask pattern 77 as a mask. As a result, the gate electrodes 25 of both the memory cell MC and the selection gate transistor SGT, and the bottom electrode 32 of the bit line contact BC are formed.

Here, the first polycrystalline silicon 71 is set to be the floating gate electrode 12 in the memory cell MC. The inter-gate insulator 72 is set to be the inter-gate insulator 13 and the second polycrystalline silicon 73 is set to be the control gate electrode 14, respectively, in the memory cell MC. Further, the inter-electrode insulator 72 and the second polycrystalline silicon 73 are set to be the lower layer gate electrode 22, the inter-gate insulator 23 and the upper layer gate electrode 24 in the selection gate transistor SGT. Further, the first polycrystalline silicon 71, the inter-electrode insulator 72 and the second polycrystalline silicon 73 are set to be the bottom electrode 32, the inter-gate insulator 33 and the top electrode 34, respectively, in the bit line contact BC.

In this time-point, the word line WL from a view point of the upper surface has the closed loop in which each end of the two linear portions 77-1 is connected by the linear connection portion 77-2. Further, when etching is performed as a state in which the misalignment is generated in the etching process, the bottom electrode 32 in the opening GI may not be covered. Therefore, a width of the bottom electrode 32 is set to be wider than a width of the opening GI in the gate length direction. In such a manner, an alignment margin with the bottom electrode 32 in the opening GI can be larger. As a result, the gate insulator 11 is formed between the bottom electrode 32 and the semiconductor substrate 10 at the end portion of the bottom electrode 32 in the bit line contact BC.

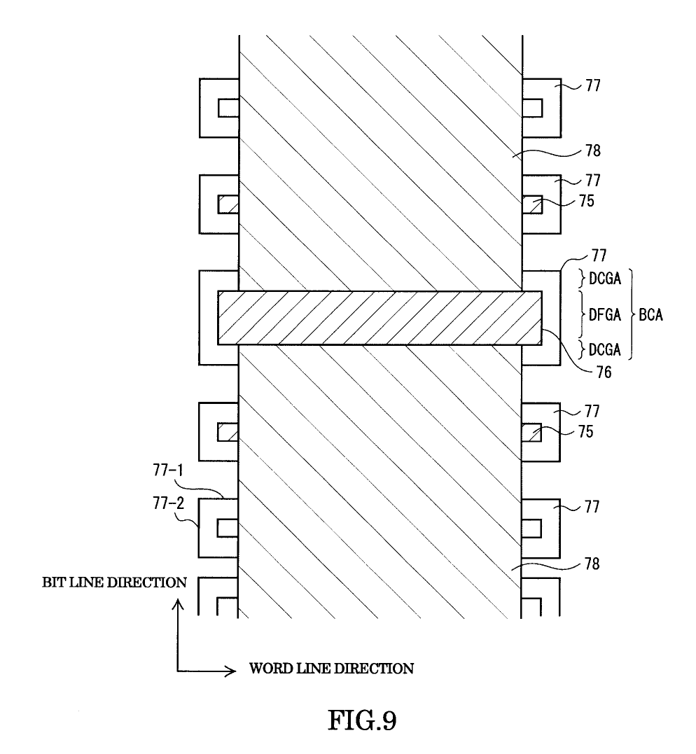

As shown in FIG. 9, a fourth mask pattern 78 is formed for opening the linear connection portion 77-2 of the side-wall mask pattern 77 and the connection portion DFGA of the bit line contact area BCA. In this process, an end portion of the linear portion 77-1 may be partially exposed from the fourth mask pattern 78.

The second mask pattern 75, the third mask pattern 76, the side-wall mask pattern 77, the control gate electrode 14, the upper layer gate electrode 24, the top electrode 34 and the inter-gate insulators 13,23,33 are etched using the fourth mask pattern 78 as a mask, for example, by RIE. Further, the etching process is performed to the portion of the upper portion of the bottom electrode 32 without leaving the top electrode 34.

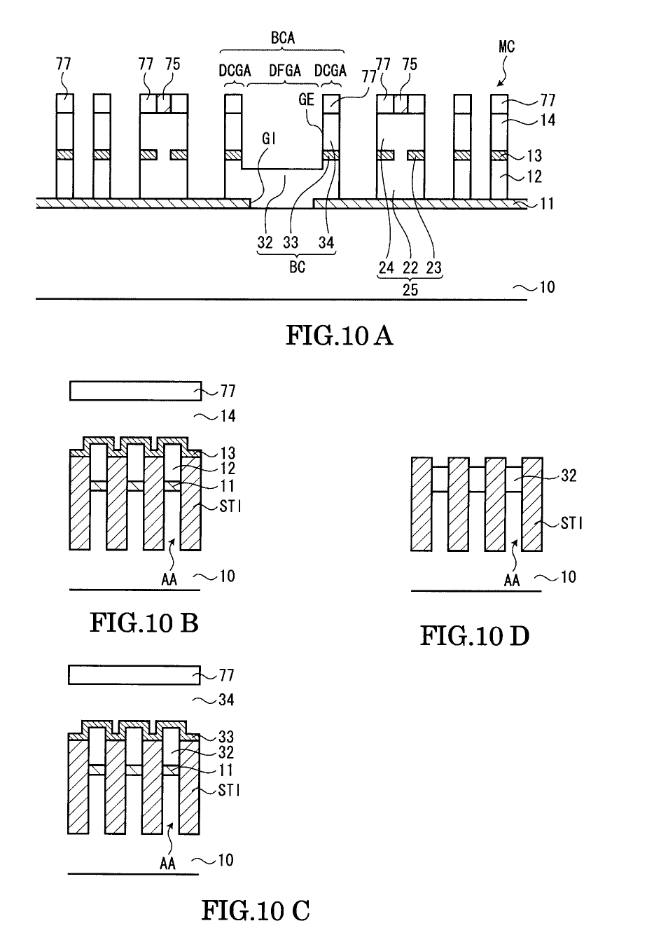

As a result, as shown in FIG. 10, an opening GE, a bottom surface of which is in the bottom electrode 32, is formed in the connection portion DFGA of the bit line contact area BCA. At the same process, the control gate electrode 14 and the inter-gate insulator 13 of the memory cell MC in the linear connection portion 77-2 are also removed. As a result, the word lines WL extended to the word line direction is formed in a portion where a designed interval is arranged between the adjacent word lines WL in the bit line direction.

The inter-gate insulator 33 and the top electrode 34 are formed by the opening GE, where the inter-gate insulator 33 is formed on an upper portion of the bottom electrode 32 in the side-wall portion DCGA, and the top electrode 34 is formed on the bottom electrode 32 via the inter-gate insulator 33. Further, the upper surface of the bottom electrode 32 in the connection portion DFGA becomes lower than the upper surface of the isolation insulator STI by etching to the portion of the upper portion of the bottom electrode 32. In other word, the bottom electrode 32 formed on each active area AA is separated by the isolation insulator STI.

The side-wall mask pattern 77 is only formed on the top electrode 34 in the connection portion DFGA, however, the third mask pattern 76 may be partially leaved on the top electrode 34.

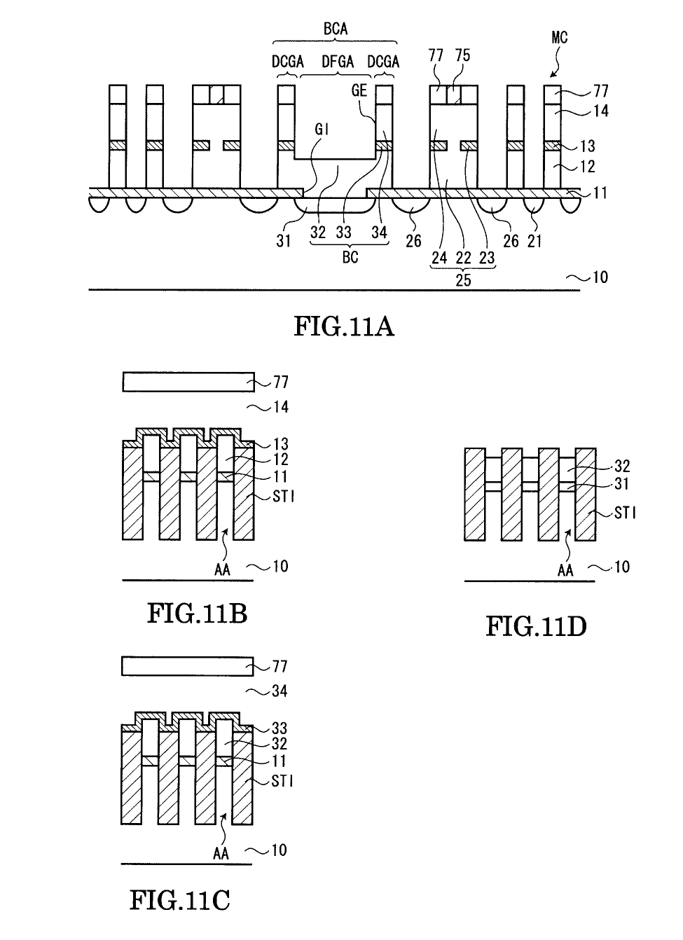

As shown in FIG. 11, arsenic or phosphorous, for example, as an impurity is implanted into the semiconductor substrate 10 by ion-implantation using the gate electrode 25 of both the memory cell MC and the selection gate transistor SGT, and the bit line contact of the bottom electrode 32 as a mask.

As a result, the source-drain diffusion layers 21, 26 are formed to sandwich a portion between the adjacent memory cells MC and the gate electrode 25.

A resist mask for opening the connection portion. DFGA is formed, and arsenic or phosphorous, for example, as an impurity is implanted into the semiconductor substrate 10 by ion-implantation. As a result, the diffusion layer 31 is formed in the surface of the semiconductor substrate 10 to surround the opening GI. The resist mask may be added to the connection portion DFGA, and a portion of the opening side-wall portion DCGA may be opened. In such a manner, the diffusion layer 31 can be formed in the surface of the semiconductor substrate 10 to surround the opening GI as using the side-wall mask pattern 77 and the top electrode 34 formed in the side-wall portion DCGA as a mask.

Further, the bottom portion of the diffusion layer 31 is arranged to be shallower than the bottom portion of the isolation insulator STI. As a result, the diffusion layer 31 can be electrically isolated in the word line direction in the case that the contact plug 35 is formed on each of the bottom electrodes 32.

Further, the diffusion layer 31 can be formed immediately forming the opening GI by ion-implantation. Accordingly, the diffusion layer 31 can be formed as the same time as forming the mask as the opening GI. In such a manner, the processing steps can be simplified.

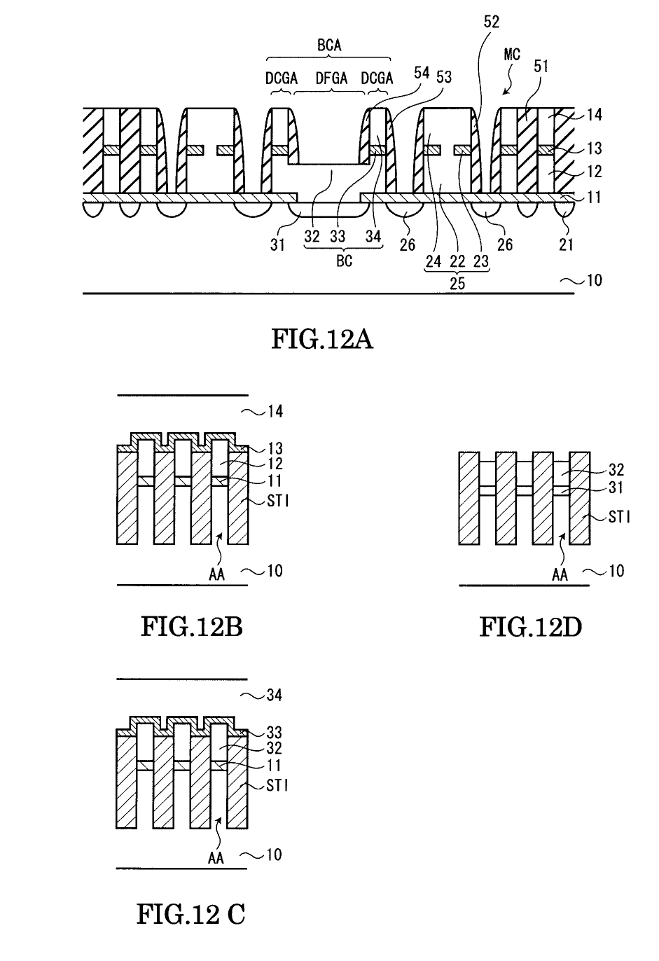

A silicon oxide film, for example, is entirely deposited on the semiconductor substrate 10 to embed between the memory cells, between the memory cell MC and the gate electrode 25 and between the gate electrode 25 and the bit line contact BC. The silicon oxide film is selectively removed by anisotropic etching. As shown in FIG. 12A, the side-wall insulator 51 is formed between the memory cells MC, side-wall insulators 52 are formed on a side surface of the memory cell MC opposed to the gate electrode 25 and a side surface of the gate electrode 25. Further, a side-wall insulator 53 is formed on a side surface of the bit line contact BC opposed to the gate electrode 25. Further, a side-wall insulator 54 is formed on a side surface of the top electrode 34 in the bit line contact BC and a bottom portion of the side-wall insulator 54 is contacted to the bottom electrode 32. The second mask pattern 75 and the side-wall mask pattern 77 are removed.

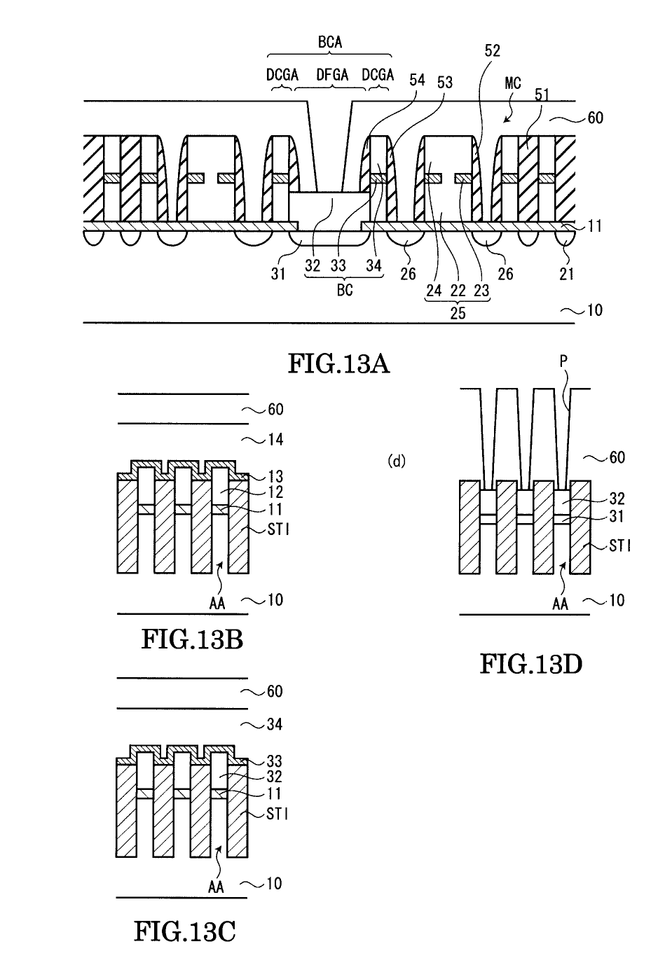

A silicon oxide film is entirely deposited on the semiconductor substrate 10, for example, to form an opening P in a region in which the contact plug 35 is formed to expose the bottom electrode 32. Accordingly, as shown in FIG. 13, an insulator 60 having the opening P is formed in a region, where the contact plug 35 is formed, to cover the memory cell MC, the gate electrode 25 and the bit line contact BC. An insulator which has a different material from the insulator 60 can be used as the side-wall insulator 54. In such a manner, in the case that the opening P come closer to the side of the top electrode 34 due to misalignment, the side surface of the top electrode 34 is exposed by the opening P caused by etching rate difference between the side-wall insulator 54 and the insulator 60.

A conductive layer is embedded in the opening P to form the contact plug 35. As subsequent processes, the upper layer wiring 61 is formed to connect to the bit line contact. BC by using well-known technique to complete the nonvolatile semiconductor memory device as shown in FIG. 2.

### (Modification of the Fabrication Method)

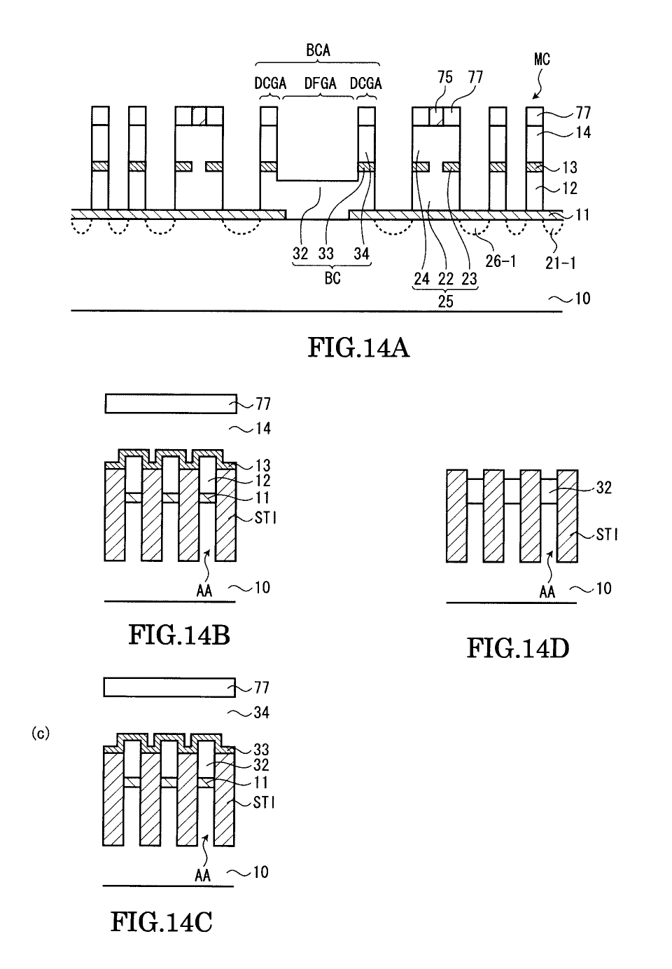

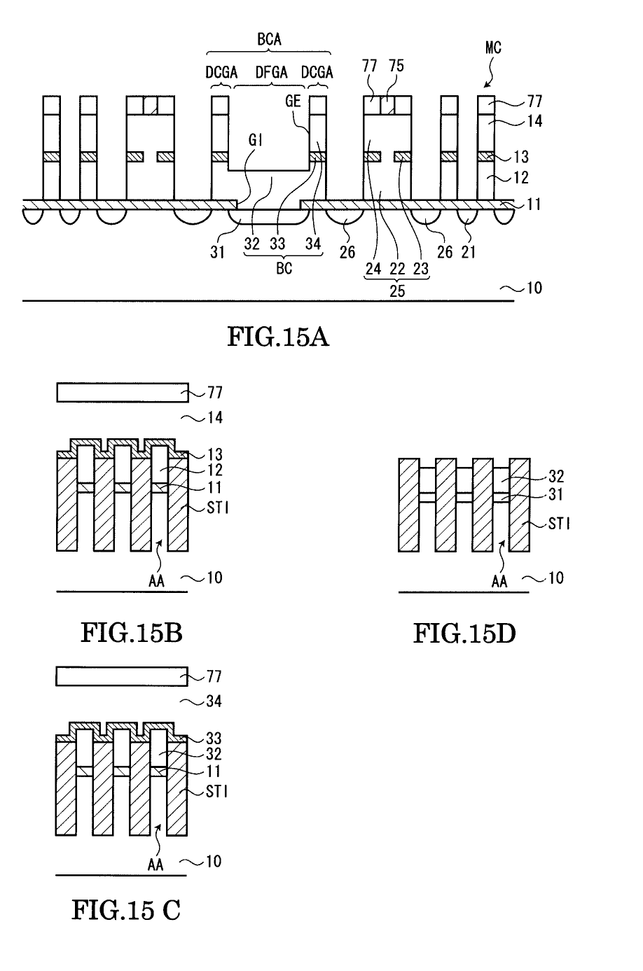

Next, a method of fabricating the semiconductor memory device in a modification of the first embodiment is explained by using FIGS. 14-15. FIGS. 14A, 15A, are cross-sectional views taken along A-A line in FIG. 1. FIGS. 14B, 14B are cross-sectional views taken along B-B line in FIG. 1. FIGS. 14C, 15 are cross-sectional views taken along C-C line in FIG. 1. FIGS. 14D, 15D are cross-sectional views taken along D-D line in FIG. 1. FIGS. 5-7, 9 are plane views corresponding to FIG. 1. Explanation on the process step of the modification as the same as the step in the first embodiment is omitted. Throughout the attached drawings, similar or same reference numerals show similar, equivalent or same components.

In the processes shown in FIG. 4, at least a lower layer in the first polycrystalline silicon is doped with N-type impurity such as arsenic or phosphorous. The processes from the step mentioned above to FIG. 11 are the same as the first embodiment.

Arsenic or phosphorous, for example, as an impurities are implanted into the semiconductor substrate 10 by ion-implantation using the gate electrode 25 of the selection gate transistor SGT, and the bit line contact of the bottom electrode 32 as a mask. As a result, as shown in FIG. 14A, impurity implanted regions 21-1, 26-1 are formed to sandwich a portion of the memory cell MC and the gate electrode 25.

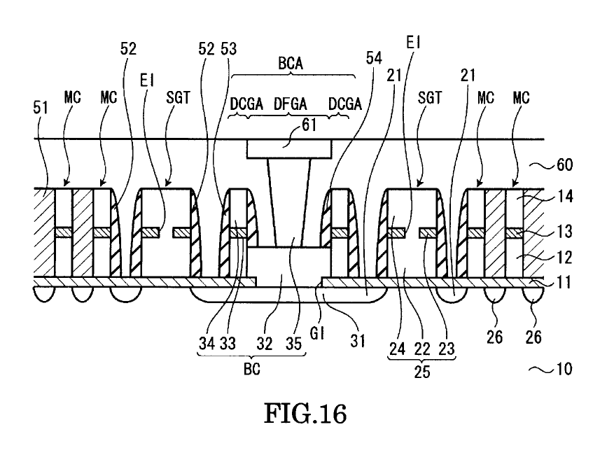

As shown in FIG. 15, impurities in the impurity implanted regions 21-1, 26-1 are activated by annealing, so that the source-drain diffusion layers 21, 26 are formed to sandwich the portion of the memory cell MC and the gate electrode 25. At the same time, n-type impurities doped in the polycrystalline silicon 71 are diffused into the semiconductor substrate 10 through the opening GI to form the diffusion layers 31 in each active areas AA. Consequently, the diffusion layer 31 is formed with self-align manner. Further, the diffusion layer 31 may be directly contacted to the source-drain diffusion layer 21, as shown in FIG. 16 which is a case according to the first embodiment, for example.

Further, the bottom portion of the connection diffusion layer 31 is arranged to be shallower than the bottom portion of the isolation insulator STI. As a result, the diffusion layer 31 can be electrically isolated in the word line direction in the case that the contact plug 35 is formed on each of the bottom electrodes 32.

According to the fabrication method of the modification, p-channel transistors of the memory cell MC and the selection gate transistor SGT are set to be a surface type. As a result, the diffusion layer 31 can be formed in self-align by using N-type impurities doped in at least lower layer of the first polycrystalline silicon.

As the diffusion layer 31 can be simultaneously formed with annealing for impurity activation to form the diffusion layers 21, 26. As a result, the processing steps can be simplified.

According to the semiconductor memory device and the method of fabricating the semiconductor memory device, at least effects mentioned below are obtained. First, an aspect ratio of the bit line contact BC can be smaller. As mentioned above, the bit line contact BC is formed by forming the contact plug 35 on the upper surface of the bottom electrode 32. Here, a height of the contact plug 35 is a distance from the bottom surface of the bit line BL to the upper surface of the bottom electrode 32. Namely, a contact plug 35 can be decreased the height which is corresponding to the height of the bottom electrode 32. In such a manner, process margin can be improved and the shape of the contact plug 35 can be stabilized.

Secondly, resistance of the bit line contact BC can be decreased. The bottom electrode 32 with a wider width than the diameter of the contact plug 35 is formed on the bottom portion of the bit line contact BC, which leads to totally decrease the bit line contact BC. Further, it is not necessary to widen the diameter of the contact plug 35 for decreasing contact resistance. Therefore, the structure has a great advantage for miniaturization of a nonvolatile semiconductor memory device.

Thirdly, the method is superior to decreasing production cost. The bottom electrode 32 can be simultaneously formed with the floating gate electrode 12. Further, removing the top electrode 34 and the inter-gate insulator 33 in the connection portion DFGA is simultaneously performed with removing the linear connection portion 77 with the closed loop shape in which the end portion of each of the two linear portion 77-1 is connected to the linear connection portion 77-2. As a result, the shape of the contact electrode can be improved and the contact resistance can be lowered without increasing the processing steps.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor memory device, comprising:
a memory cell having a floating gate electrode above a semiconductor substrate via a first gate insulator and a control gate electrode above the floating gate electrode via a first inter-gate insulator;
a contact electrode having a bottom electrode contacted to an upper surface of the semiconductor substrate, top electrodes via second inter-gate insulators on both edge portions of the bottom electrode, and a plug electrode contacted to an upper surface of the bottom electrode between the top electrodes.

2. The device of claim 1, further comprising:
a side-wall insulator disposed on a side surface of each of the top electrode, a bottom portion of the side-wall insulator contacting to the bottom electrode.

3. The device of claim 1, further comprising:
a second gate insulator disposed between an edge portion of the bottom electrode between the contact electrode and the semiconductor substrate.

4. The device of claim 1, further comprising:
a first diffusion layer formed in the upper surface of the semiconductor substrate and contacted to the bottom electrode.

5. The device of claim 1, wherein
the bottom electrode has conductive impurities.

6. The device of claim 1, wherein
a material of the first gate insulator is the same as a material of the second gate insulator material.

7. The device of claim 1, wherein
a material of the floating gate electrode is the same as a material of the bottom electrode.

8. The device of claim 1, wherein
a material of the control gate electrode is the same as a material of the top electrode.

9. The device of claim 1, further comprising:
a selection gate transistor having a gate electrode above the semiconductor substrate via the first gate insulator and third diffusion layers formed in the surface layer of the semiconductor substrate, and the third diffusion layers sandwiching a portion of the surface layer of the semiconductor substrate immediately beneath the gate electrode.

10. The device of claim 1, wherein
each of the third diffusion layers is electrically connected to the first diffusion layer.

11. A semiconductor memory device, comprising:
a semiconductor substrate;
an isolation insulator extending to a first direction and separating the semiconductor substrate into a plurality of element regions,
a memory cell having a floating gate above the element region via a gate insulator, a control gate electrode above the floating gate electrode via a first inter-gate insulator;
a plurality of contact electrodes arranged along a second direction crossing with the first direction, each of the contact electrodes having a bottom electrode contacted to an upper surface of the element region, top electrodes above the bottom electrode via second inter-gate insulators at both edge portions of the bottom electrode, the bottom electrode in the contact electrode isolated by the isolation insulator and connected to each of the top electrodes in the contact electrode, and a plug electrode between the top electrodes contacting to an upper surface of the bottom electrode.

12. A method of fabricating a semiconductor memory device comprising a memory cell region and a contact region in which a memory cell and a contact electrode are disposed, respectively, comprising:
forming a gate insulator on a semiconductor substrate;
removing a portion of the gate insulator in the contact region to expose the semiconductor substrate to form an opening;
forming a first poly silicon above both the semiconductor substrate in the memory cell region and the semiconductor substrate exposed in the contact region;
etching the first poly silicon, the gate insulator and the semiconductor substrate to form an isolation groove along a first direction;
embedding an insulator into the isolation groove to form an isolation insulator to separate the semiconductor substrate into a plurality of element regions;
forming an inter-gate insulator and a second poly silicon above the semiconductor substrate;
processing the first poly silicon, the inter-gate insulator and the second poly silicon to form both a first electrode structure with a closed loop shape along a second direction crossing the first direction in the memory cell region and a second electrode structure in the contact region along the second direction;
removing both the inter-gate insulator and the second poly silicon in an edge portion of the closed loop shape of the first electrode structure, and the inter-gate insulator and the first poly silicon in a portion of a center area of the second electrode structure to separately form the first poly silicon above the element region; and
forming a contact plug on the first poly silicon between the second poly silicon in the contact region.

13. The method of claim 12, further comprising:
introducing conductive impurities into the semiconductor substrate using the first electrode structure and the second electrode structure as masks.

14. The method of claim 13, further comprising:
introducing the conductive impurities into the first poly silicon of the second electrode structure.

15. The method of claim 13, wherein the conductive impurities are doped in the first poly silicon in forming the first poly silicon.

16. The method of claim 12, further comprising:
diffusing the conductive impurities doped in the first poly silicon of the second electrode structure into the semiconductor substrate through the opening.
